(19) United States
(12) Patent Application Publication
(10) Pub. No.: US 2003/0062567 A1
(43) Pub. Date: Apr. 3, 2003

(54) Non volatile dielectric memory cell structure with high dielectric constant capacitive coupling layer

(76) Inventors: Wei Zheng, Sunnyvale, CA (US); Wenmei Lei, Sunnyvale, CA (US); Arvind Halliyal, Cupertino, CA (US); Mark Randolph, San Jose, CA (US)

Correspondence Address: Mark D. Saralino, Renner, Otto, Boisselle, & Sklar, L.L.P., 19th Floor, 1621 Euclid Avenue, Cleveland, OH, 44115, US

(21) Appl. No.: 09/966,638

(22) Filed: Sep. 28, 2001

(51) Int. Cl. H01L 29/788

(52) U.S. Cl. 257/316

(57) ABSTRACT

A dielectric memory cell comprises a substrate which includes a source region, a drain region, and a channel region positioned there between. A multilevel charge trapping dielectric is positioned on the surface of the substrate and a control gate is positioned on the surface of the dielectric and is positioned over the channel region. The multilevel charge trapping dielectric includes a tunneling dielectric adjacent to the substrate, a high dielectric constant capacitive coupling dielectric adjacent to the control gate, and a charge trapping dielectric positioned there between.

### TECHNICAL FIELD

The present invention relates generally to a integrated circuit non volatile dielectric memory cell devices and, more specifically to improvements in scalable non volatile dielectric memory cell device structure and to methods of erasing non volatile dielectric memory cell devices.

### BACKGROUND OF THE INVENTION

Conventional floating gate flash memory types of EEPROMs (electrically erasable programmable read only memory), utilize a memory cell characterized by a vertical stack of a tunnel oxide (SiO₂), a polysilicon floating gate over the tunnel oxide, an interlayer dielectric over the floating gate (typically an oxide, nitride, oxide stack), and a control gate over the interlayer dielectric positioned over a crystalline silicon substrate. Within the substrate are a channel region positioned below the vertical stack and source and drain diffusions on opposing sides of the channel region.

The floating gate flash memory cell is programmed by inducing hot electron injection from the channel region to the floating gate to create a non volatile negative charge on the floating gate. Hot electron injection can be achieved by applying a drain to source bias along with a high control gate positive voltage. The gate voltage inverts the channel while the drain to source bias accelerates electrons towards the drain. The accelerated electrons gain 5.0 to 6.0 eV of kinetic energy which is more than sufficient to cross the 3.2 eV Si—SiO₂ energy barrier between the channel region and the tunnel oxide. While the electrons are accelerated towards the drain, those electrons which collide with the crystalline lattice are re-directed towards the Si—SiO₂ interface under the influence of the control gate electrical field and gain sufficient energy to cross the barrier.

Once programmed, the negative charge on the floating gate increases the threshold voltage of the FET characterized by the source region, drain region, channel region, and control gate. During a “read” of the memory cell, the magnitude of the current flowing between the source and drain at a predetermined control gate voltage indicates whether the flash cell is programmed.

The erase function is typically performed using Fowler-Nordheim (FN) tunneling through the floating gate/tunnel oxide barrier. More specifically, large negative voltage is applied to the control gate, a moderate positive voltage is applied to the source, and the drain is floated. Under such bias conditions, the electrons stored on the floating gate tunnel into the tunnel oxide and are swept into the source region.

More recently dielectric memory cell structures have been developed. A dielectric memory cell is characterized by a vertical stack of an insulating bottom oxide layer, a charge trapping dielectric layer, an insulating top oxide layer, and polysilicon control gate positioned on top of a crystalline silicon substrate. Within the substrate are a channel region positioned below the vertical stack and source and drain diffusions on opposing sides of the channel region. This particular structure of a silicon channel region, bottom oxide, nitride, top oxide, silicon control gate is often referred to as a SONOS device.

Similar to the floating gate device, a SONOS device is programmed utilizing hot electron injection. However, it should be appreciated that because the injected electrons are trapped in the nitride/bottom oxide junction, the charge remains close to the source region or the drain region from which the electrons were injected. As such, the SONOS device can be used to store two bits of data per cell.

Scalability of such memory cell is effected by the minimum feature size of the fabrication equipment and by a minimum channel length requirement which is a function of the total thickness of the ONO stack.

A SONOS device can be erased by injecting hot holes created by Band to Band (BTB) tunneling. More specifically, the source is floated and an appropriate positive voltage is applied to the drain region to create the BTB tunneling. A negative voltage is applied to the control gate to accelerate holes towards the source side charge trapping layer.

A problem associated with hot hole injection is that it damages the bottom oxide and its interface with the silicon substrate. More specifically, a large portion of the injected holes are trapped in the bottom tunnel oxide and, the trapped holes generate interface states between the bottom tunnel oxide layer and the silicon channel. Another problem associated with dielectric memory cell structures is that the minimum required thicknesses of the oxide, nitride, oxide stack limits the scaling of the channel length to smaller dimensions.

Therefore, there is a need in the art for a dielectric memory cell structure which does not suffer the disadvantages discussed above. More specifically, there is a need in the art for a dielectric memory cell structure which can provide for further scaling of the channel to smaller dimensions and which provides for an erase method that causes less cell damage.

### SUMMARY OF THE INVENTION

A first aspect of the present invention is to provide a novel dielectric memory cell structure. The dielectric memory cell structure comprises a substrate with a source region, a drain region, and a channel region positioned between the source region and the drain region. A multilevel charge trapping dielectric is positioned on the surface of the substrate and polysilicon control gate positioned on the surface of the multilevel charge trapping dielectric and positioned over the channel region.

The multilevel charge trapping dielectric includes: a) a bottom layer adjacent to the substrate which comprises a first dielectric with a first dielectric constant; b) a top layer adjacent to the control gate comprising a second dielectric with a second dielectric constant which is higher than the first dielectric constant; and c) a charge trapping layer positioned between the bottom layer and the top layer of a third dielectric with charge trapping properties.

The bottom layer first dielectric may be silicon dioxide and the charge trapping third dielectric may be a nitride layer. The top layer second dielectric may be dielectric selected from the group of an aluminum oxide compound, a hafnium oxide compound, and a zirconium oxide compound. More specifically, the top layer second dielectric may be a dielectric selected from the group of Al₂O₃, HfSiₓO_{y}, HfO₂, ZrO₂, and ZrXiₓO_{y}.

A second aspect of the present invention is to provide a tunneling erasable charge trapping dielectric for a non-volatile storage of electrons in a dielectric memory cell. The charge trapping dielectric comprises: a) a tunneling dielectric positioned adjacent to a channel region of the dielectric memory cell; b) a high dielectric constant capacitive coupling dielectric adjacent to a control gate of the dielectric memory cell; and c) a charge trapping dielectric positioned between the tunneling dielectric and the capacitive coupling dielectric.

The tunneling dielectric may be silicon dioxide and the charge trapping dielectric may be a nitride compound. The capacitive coupling dielectric may be dielectric selected from the group of an aluminum oxide compound, a hafnium oxide compound, and a zirconium oxide compound. More specifically, the capacitive coupling dielectric may be a dielectric selected from the group of Al₂O₃, HfSiₓO_{y}, HfO₂, ZrO₂, and ZrXiₓO_{y}.

### BRIEF DESCRIPTION OF THE DRAWINGS

FIG. 1 is a cross section diagram of a dielectric memory cell in accordance with one embodiment of this invention

FIG. 2 is a flow chart diagram representing exemplary processing steps for fabricating the dielectric memory cell of FIG. 1;

FIG. 3a is a cross section diagram of a processing step in the fabrication of the dielectric memory cell of FIG. 1;

FIG. 3b is a cross section diagram of a processing step in the fabrication of the dielectric memory cell of FIG. 1;

FIG. 3c is a cross section diagram of a processing step in the fabrication of the dielectric memory cell of FIG. 1;

FIG. 3d is a cross section diagram of a processing step in the fabrication of the dielectric memory cell of FIG. 1;

FIG. 3e is a cross section diagram of a processing step in the fabrication of the dielectric memory cell of FIG. 1; and

FIG. 3f is a cross section diagram of a processing step in the fabrication of the dielectric memory cell of FIG. 1.

### DESCRIPTION OF THE PREFERRED EMBODIMENTS

The present invention will now be described in detail with reference to the drawings. In the drawings, like reference numerals are used to refer to like elements throughout.

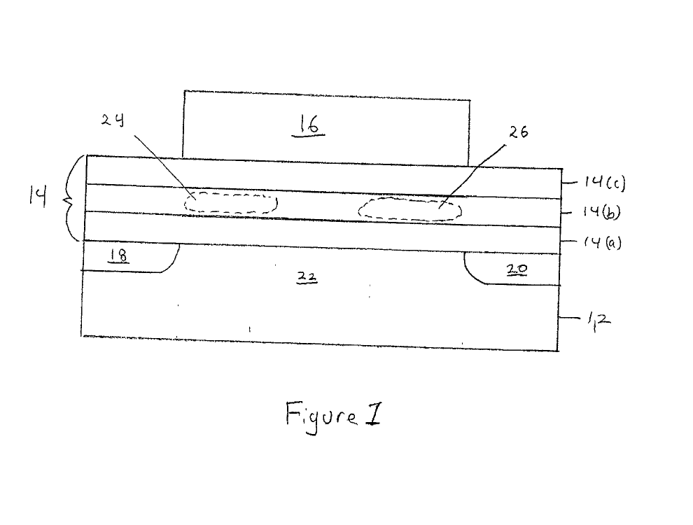

Referring to FIG. 1, a cross section view of a dielectric memory cell 10 formed on a semiconductor substrate 12 is shown. The diagram is not drawn to scale and the dimensions of some features are intentionally drawn larger than scale for purposes of showing clarity.

The memory cell 10 is shown as a substantially planar structure formed on the bulk substrate 12. However, it should be appreciated that the teachings of this invention may be applied to both planar, fin formed, and other dielectric memory cell structures which may be formed on either bulk substrates, SOI substrates or other substrate structures.

The memory cell 10 includes a multi layer charge trapping dielectric 14 positioned between the bulk substrate 12 and a polysilicon control gate 16.

The bulk substrate 12 preferably comprises lightly doped p (or n) -type silicon and includes an n- (or p-) type implanted source region 18 and an n- (or p) type drain region 20 on opposing sides of a central channel region 22 which is positioned beneath the polysilicon control gate 16.

The charge trapping dielectric 14 comprises three layers. The bottom layer, or tunneling layer, 14(a) comprises a first dielectric material, and the top layer, or capacitive coupling layer, 14(c) comprises a second dielectric material with a dielectric constant higher than that of the first dielectric material, and the middle charge trapping layer 14(b) comprises a third dielectric material which is capable of electron trapping,

In the exemplary embodiment, the first dielectric material comprising the tunneling layer 14(a) is silicon dioxide and its thickness is within a range of about 50 Å to about 150 Å. An embodiment with a more narrow bracket includes a tunneling layer 14(a) thickness within a range of about 60 Å to about 90 Å and even narrower yet, a tunneling layer 14(a) thickness of about 70 Å to about 80 Å.

The third dielectric material comprising the charge trapping layer 14(b) may be silicon nitride and its thickness is within a range of about 20 Å to about 80 Å. An embodiment with a more narrow bracket includes a charge trapping layer 14(b) thickness within a range of about 30 Å to about 70Å and even narrower yet, a charge trapping layer 14(b) thickness of about 50Å to about 60 Å.

The second dielectric material comprising the capacitive coupling layer 14(c) includes a material with a high dielectric constants such as Al₂O₃ and has a thickness within a range of about 70Å to 130 Å. An embodiment with a more narrow bracket includes a capacitive coupling top layer 14(c) thickness within a range of about 80Å to about 120Å and even narrower yet, a capacitive coupling top layer 14(c) thickness of about 90Å to about 100 Å.

The second dielectric material may alternatively comprise a material with a high dielectric constant selected from the group of HfSiOₓ, HfO₂, ZrO₂, and other materials with similarly high dielectric constants.

The memory cell 10 is configured to store two bits of data within the cell. The first bit of data is represented by the storage of trapped electrons in a region 24 of the charge trapping layer 14(b) adjacent to the source region 18. The second bit of data is represented by the storage of trapped electron in a region 26 of the charge trapping layer 14(b) adjacent to the drain region 20.

The memory cell 10 is programmed utilizing a hot electron injection technique. More specifically, programming of the first bit of data comprises injecting electrons into region 24 and programming the second bit of data comprises injecting electrons into region 26. Hot electron injection into region 24 comprises applying a source 18 to drain 20 bias while applying a high voltage to the control gate 16. In the exemplary embodiment, this may be accomplished by grounding the drain region 20 and applying approximately 6V to the source region 18 and 10V to the control gate 16. The control gate 16 voltage inverts the channel region 22 while the source region 18 to drain region 20 bias accelerates electrons into the channel region 22 towards the drain region 20. The 5.5 eV to 6 eV kinetic energy gain of the electrons is more than sufficient to surmount the 3.1 eV to 3.5 eV energy barrier at the channel region 22/bottom dielectric layer 14(a) interface and, while the electrons are accelerated towards the drain region 20, the high voltage on the control gate 16 redirects the electrons towards the dielectric layer 14. Those electrons which cross the interface into the dielectric layer 14 are trapped in the charge trapping layer 14(b) in the region 24.

Similarly, the second bit of data, comprising the storage of electrons in region 26, may be programmed by grounding the source region 18, and applying approximate 6V to the drain region 20 and 10V to the control gate 16. Again, the drain region 20 to source region 18 bias accelerates electrons into the channel region 22 towards the source region 18 and the high voltage on the control gate 16 redirects the electrons towards the dielectric layer 14. Those electrons which cross the interface into the dielectric layer 14 are trapped in the charge trapping layer 14(b) in the region 26.

The presence of trapped electrons within regions 24 and 26 each effect depletion within the channel region 22 and as such effect the threshold voltage of a field effect transistor (FET) characterized by the control gate 16, the source region 18 and the drain region 20. Therefore, each bit may be “read”, or more specifically, the presence of electrons stored within regions 24 and 26 may be detected, by operation of the FET. More specifically, the presence of electrons stored within region 24 may be detected by applying a positive voltage to the control gate 16 and a lesser positive voltage to the to the drain region 20 while the source region 18 is grounded. The current flow is then measured at the drain region 20. If there are electrons trapped within region 24, no current will be measured at the drain region 20. Otherwise, if region 24 is charge neutral (e.g. no trapped electrons) then there will be a measurable current flow into the drain region 20.

Similarly, the presence of electrons stored within region 26 may be detected by applying a positive voltage to the control gate 16 and a lesser positive voltage to the to the source region 18 while the drain region 20 is grounded. The current flow is then measured at the source region 18. If there are electrons trapped within region 26, no current will be measured at the source region 18. Otherwise, if region 26 is charge neutral then there will be a measurable current flow into the source region 18.

The erasure of each bit may be accomplished by tunneling trapped electrons into the bottom tunneling dielectric layer 14(a) towards the source region 18, drain region 20, and channel region 22. More specifically, a high negative voltage is applied to the control gate 16 while the source, drain and substrate are grounded. Because the third dielectric in the top dielectric layer 14(c) comprises a material with a high dielectric constant, the strong capacitive coupling between the control gate 16 and the charge trapping layer 14(b) induces Fowler-Nordheim tunneling of trapped electrons through the silicon dioxide bottom dielectric layer 14(c).

It should be appreciated that the erasure of the dielectric memory cell 10 utilizing Fowler-Nordheim tunneling of electrons through the bottom dielectric layer 14(c) provides for improved reliability of the device by avoiding the break down effects of erasure utilizing hot hole injection from the channel region 22. It should also be appreciated that FN tunneling of electrons through the bottom dielectric layer 14(c) neutralizes any charge that may be stored between the regions 24 and 26 which, if not properly neutralized during a program/erase cycle can cause erratic reading.

It should further be appreciated that the use of a dielectric with a high dielectric constant in the top dielectric layer 14(c) improves capacitive coupling between the control gate and the channel region 22 which permits scaling of the channel length to shorter dimensions without experiencing erratic reading results due channel depletion adjacent to the source/channel and drain/channel junctions.

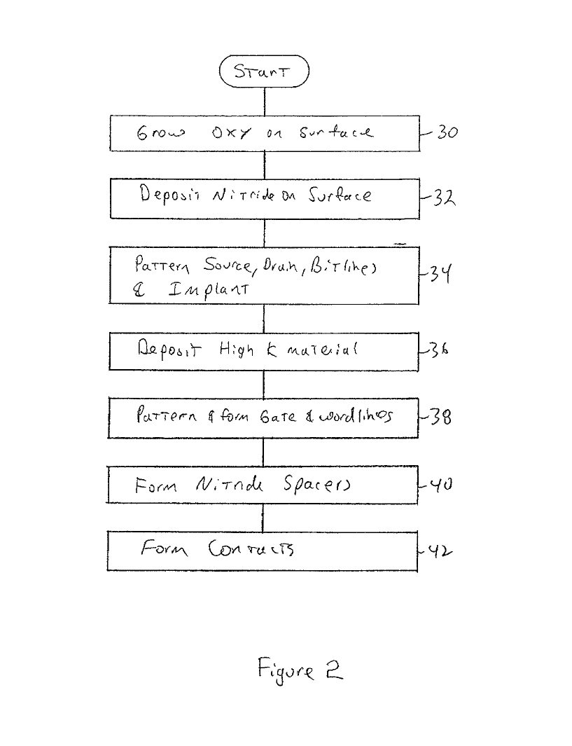

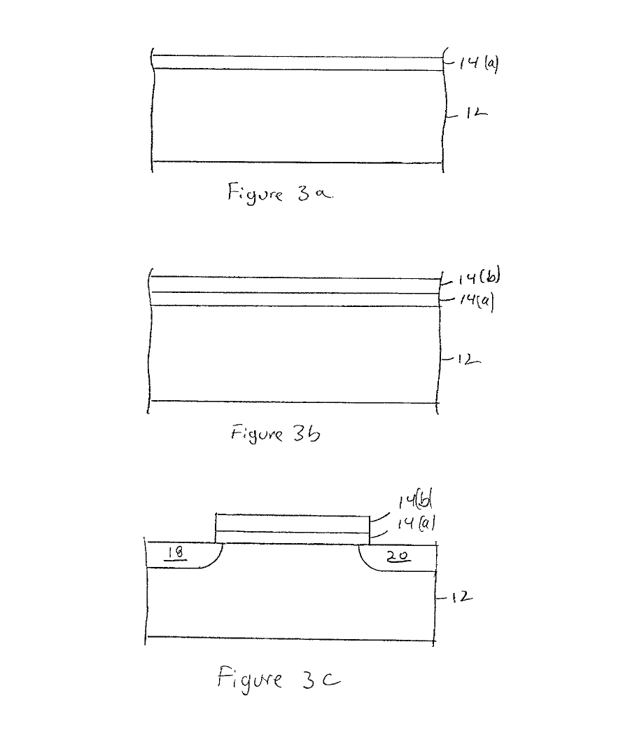

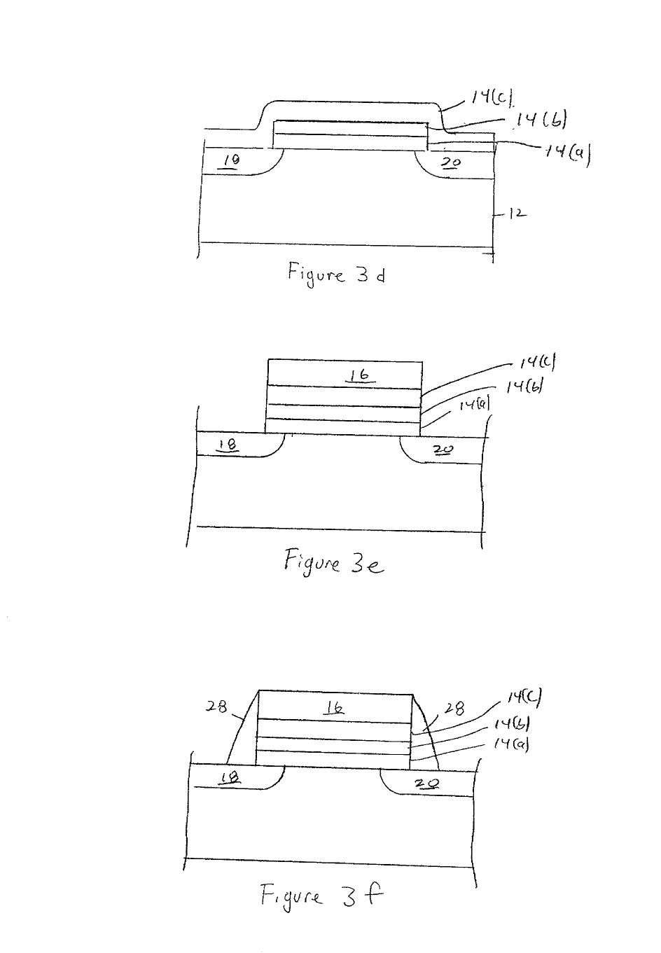

Turning to the flowchart of FIG. 2 and the cross sectional diagrams of FIG. 3(a) to FIG. 3(f), exemplary processing steps for fabricating the dielectric memory cell 10 of FIG. 1 in a planar structure are represented.

Step 30 represents growing a layer of oxide 14(a) approximately 70Å to 80Å in thickness on the surface of the p-type bulk wafer 12 as shown in FIG. 3(a). Step 32 represents depositing a layer of nitride 14(b) approximately 50Å to 60Å in thickness on the surface of the oxide layer 14(a) as is shown in FIG. 3(b).

Step 34 represents patterning and implanting the source region 18, drain region 20, and bit lines (not shown) as set forth in FIG. 3(c). More specifically, a layer of photoresist is applied to the top of the nitride 14(b) and patterned to expose the source region 18, drain region 20 and bit lines. The nitride is then etched to form a hard mask exposing the source region 18, drain region 20, and bit lines. Such regions are then formed in the p-type bulk wafer 12 by implanting an n-type dopant such as boron in the exposed regions.

Step 36 represents depositing the high dielectric constant material forming the capacitive coupling layer 14(c) on the surface of the exposed nitride layer 14(b) as is shown in FIG. 3(d).

Step 38 then represents forming the gate 16 on the surface of the high dielectric constant capacitive coupling layer 14(c). More specifically, a polysilicon layer 16 is applied to the surface of the capacitive coupling layer and patterned and etched using standard techniques.

Step 40 represents forming nitride spacers 28 on the side of the dielectric layers 14(a), 14(b), and 14(c) and the gate 16 as is shown in FIG. 3(f). More specifically, a layer of nitride is applied over the surface of the wafer and anisotropically etched to form the spacers. Thereafter step 42 represents forming contacts to the source region 18, drain region 20, and control gate 16.

Although the dielectric memory cell of this invention has been shown and described with respect to certain preferred embodiments, it is obvious that equivalents and modifications will occur to others skilled in the art upon the reading and understanding of the specification. The present invention includes all such equivalents and modifications, and is limited only by the scope of the following claims.

What is claimed is:

1. A dielectric memory cell comprising:
a) a substrate comprising a source region, a drain region, and a channel region positioned there between;
b) a multilevel charge trapping dielectric positioned on the surface of the substrate; and
c) a control gate positioned on the surface of the multilevel charge trapping dielectric and positioned over the channel region; and
d) wherein the multilevel charge trapping dielectric includes:
i) a bottom layer adjacent to the substrate of a first dielectric with a first dielectric constant;
ii) a top layer adjacent to the control gate of a second dielectric with a second dielectric constant which is higher than the first dielectric constant; and
iii) a charge trapping layer positioned between the bottom layer and the top layer of a third dielectric with charge trapping properties.

2. The dielectric memory cell of claim 1, wherein the first dielectric is silicon dioxide and the third dielectric is a nitride compound.

3. The dielectric memory cell of claim 2, wherein the second dielectric is a dielectric selected from the group of an aluminum oxide compound, a Hafnium oxide compound, and a zirconium oxide compound.

4. The dielectric memory cell of claim 3, wherein the second dielectric is a dielectric selected from the group of Al₂O₃, HfSiₓO_{y}, HfO₂, ZrO₂, and ZrXiₓO_{y}.

5. The dielectric memory cell of claim 4, wherein the bottom layer has a thickness within a range of about 50Å to about 150 Å.

6. The dielectric memory cell of claim 5, wherein the bottom layer has a thickness within a range of about 60Å to about 90 Å.

7. The dielectric memory cell of claim 6, wherein the bottom layer has a thickness within a range of about 70Å to about 80 Å.

8. The dielectric memory cell of claim 5, wherein the top layer has a thickness within a range of about 70Å to 130 Å.

9. The dielectric memory cell of claim 8, wherein the top layer has a thickness within a range of about 80Å to about 120 Å.

10. The dielectric memory cell of claim 9, wherein the top layer has a thickness within a range of about 90Å to about 100 Å.

11. A charge trapping dielectric providing a non volatile storage of electrons in a dielectric memory cell, the charge trapping dielectric comprising:
a) a tunneling dielectric positioned adjacent to a channel region of the adjacent a channel region of the dielectric memory cell;
b) a high dielectric constant capacitive coupling dielectric adjacent to a control gate of the dielectric memory cell; and
c) a charge trapping dielectric positioned between the tunneling dielectric and the capacitive coupling dielectric.

12. The charge trapping dielectric of claim 11, wherein the tunneling dielectric is silicon dioxide and the charge trapping dielectric is a nitride compound.

13. The charge trapping dielectric of claim 12, wherein the capacitive coupling dielectric is a dielectric selected from the group of an aluminum oxide compound, a Hafnium oxide compound, and a zirconium oxide compound.

14. The charge trapping dielectric of claim 13, wherein the capacitive coupling dielectric is a dielectric selected from the group of Al₂O₃, HfSiₓO_{y}, HfO₂, ZrO₂, and ZrXiₓO_{y}.

15. The charge trapping dielectric of claim 14, wherein the tunneling dielectric has a thickness within a range of about 50Å to about 150 Å.

16. The charge trapping dielectric of claim 15, wherein the tunneling dielectric has a thickness within a range of about 60Å to about 90 Å.

17. The charge trapping dielectric of claim 16, wherein the tunneling dielectric has a thickness within a range of about 70Å to about 80 Å.

18. The charge trapping dielectric of claim 15, wherein the capacitive coupling dielectric has a thickness within a range of about 70Å to 130 Å.

19. The charge trapping dielectric of claim 18, wherein the capacitive coupling dielectric has a thickness within a range of about 80Å to about 120 Å.

20. The charge trapping dielectric of claim 19, wherein the capacitive coupling dielectric has a thickness within a range of about 90Å to about 100 Å.
